(19) United States
(12) Patent Application Publication
(10) Pub. No.: US 2013/0210334 A1
(43) Pub. Date: Aug. 15, 2013

(54) AIR CONDUCTING COVER FOR ELECTRONIC DEVICE

(71) Applicant: ZEU-CHIA TAN, Tu-Cheng (TW)

(72) Inventor: ZEU-CHIA TAN, Tu-Cheng (TW)

(73) Assignee: HON HAI PRECISION INDUSTRY CO., LTD., Tu-Cheng (TW)

(21) Appl. No.: 13/457,698

(22) Filed: Apr. 27, 2012

(30) Foreign Application Priority Data
Feb. 9, 2012 (TW) 101104146

(51) Int. Cl. F24F 13/10; H05K 5/02

(52) U.S. Cl. 454/184; 454/322

(57) ABSTRACT

An electronic device includes a chassis, a group of fans, and an air conducting cover. The air conducting cover defines a number of air entrances, and the fans respectively facing the corresponding air entrance. Each entrance including two opposite flaps. Air flow enters the air entrances. When air flow reversely passes through the air entrances, the air flow closes the flaps.

### BACKGROUND

1. Technical Field

The disclosure generally relates to air conducting covers, particularly to an air conducting cover which can effectively prevent air from flowing back into the electronic devices.

2. Description of Related Art

Many electronic components in an electronic device generate heat when operating. In designing an electronic device, cooling systems are used to dissipate heat generated by the electronic components to prevent the electronic components from overheating.

Many cooling systems include a group of fans and an air conducting cover. The air conducting cover is positioned above the electronic components most likely to become hot. The fans are positioned on corresponding air entrances of the air conducting cover to force airflow to enter the air conducting cover and pass through the electronic components for heat dissipation. However, when one of the fans stops working, the airflow in the air conducting cover will usually generate a return/back airflow, and go out of the air entrance corresponding to the stopping fan. Thus, the airflow of the fans is easily lost, and decreases the dissipating effects.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary air conducting cover for electronic device. Moreover, in the drawings, like reference numerals designate corresponding parts throughout the several views. Wherever possible, the same reference numbers are used throughout the drawings to refer to the same or like elements of an embodiment.

FIG. 1 is a schematic view of an embodiment of an electronic device including an air conducting cover.

FIG. 2 is a schematic view of the air conducting cover in FIG. 1 in a use state when the fans are normal.

FIG. 3 is a schematic view of the air conducting cover in FIG. 1 in a use state when the second fan stops.

FIG. 4 is a schematic view of the air conducting cover in FIG. 1 in a use state when the third and fifth fans stop.

### DETAILED DESCRIPTION

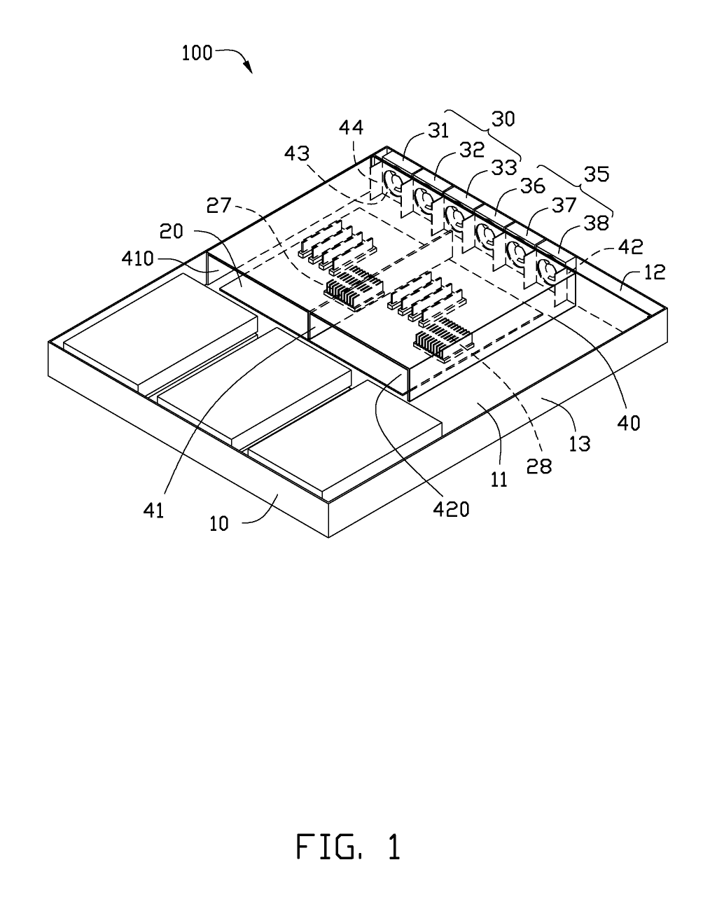

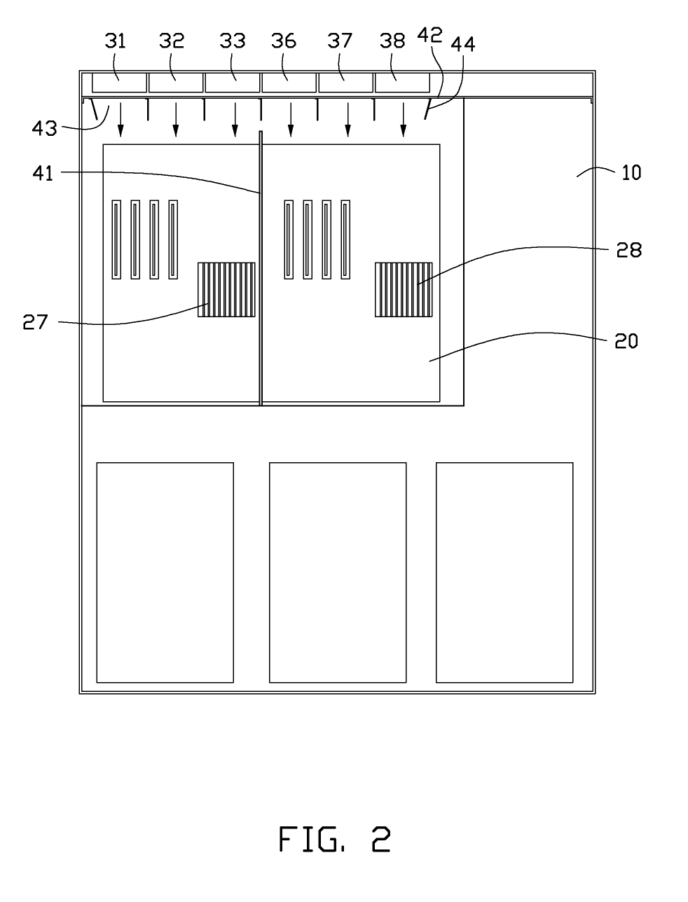

Referring to FIGS. 1 and 2, an electronic device 100 includes a chassis 10, a motherboard 20, a first electronic component 27, a second electronic component 28, a first group of fans 30, a second group of fans 35, and an air conducting cover 40.

The chassis 10 includes a base plate 11, two opposite sidewalls 12, and two opposite end walls 13 connecting the sidewalls 12. The sidewalls 12 and the ends walls 13 are substantially perpendicularly connected to edges of the base plate 11. The motherboard 20 is mounted on the base plate 11. In the exemplary embodiment, the first electronic component 27 and the second electronic component 28 are central processing units (CPUs) mounted on the motherboard 20.

The first group of fans 30 is made of three fans 31, 32, 33, and the second group of fans 35 is made of three fans 36, 37, 38. The fans 31 to 38 are arranged along a line.

The air conducting cover 40 is positioned above the motherboard 20 for covering the first electronic component 27 and the second electronic component 28. The air conducting cover 40 includes a middle partition 41 and an end plate 42. The middle partition 41 divides the air conducting cover 40 to a first space 410 and a second space. 420. The first group of fans 30 is configured for dissipating heat in the first space 410, and the second group of fans 35 is configured for dissipating heat in the second space 420.

The end plate 42 is substantially parallel to one of the sidewalls 12. The end plate 42 defines six air entrances 43. The fans 31 to 38 are positioned between the end wall 42 and the sidewall 12. Each fan faces a corresponding air entrance 43. Each air entrance 43 has two opposite flaps 44 formed on the end plate 42. The flaps 44 are integrally formed with the air conducting cover 40. Two adjacent air entrances 43 have a common flap 44. In the exemplary embodiment, there are seven flaps 44. Each flap 44 is made of metal or plastics, and is flexibly connected to the air conducting cover 40 for swing/rotating toward left sides or right side relative to the end plate. In the exemplary embodiment, when airflow returns in one air entrance 43, the return airflow can swing/rotate the corresponding flaps 42 to close the corresponding air entrance 43. A width of each flap 44 is substantially half of the diameter of the air entrance 43. In the exemplary embodiment, the flaps 44 positioned at a brim are angled toward the corresponding air entrance 43 relative to the end plate 42. The other flaps 44 are substantially perpendicular to the end plate 42.

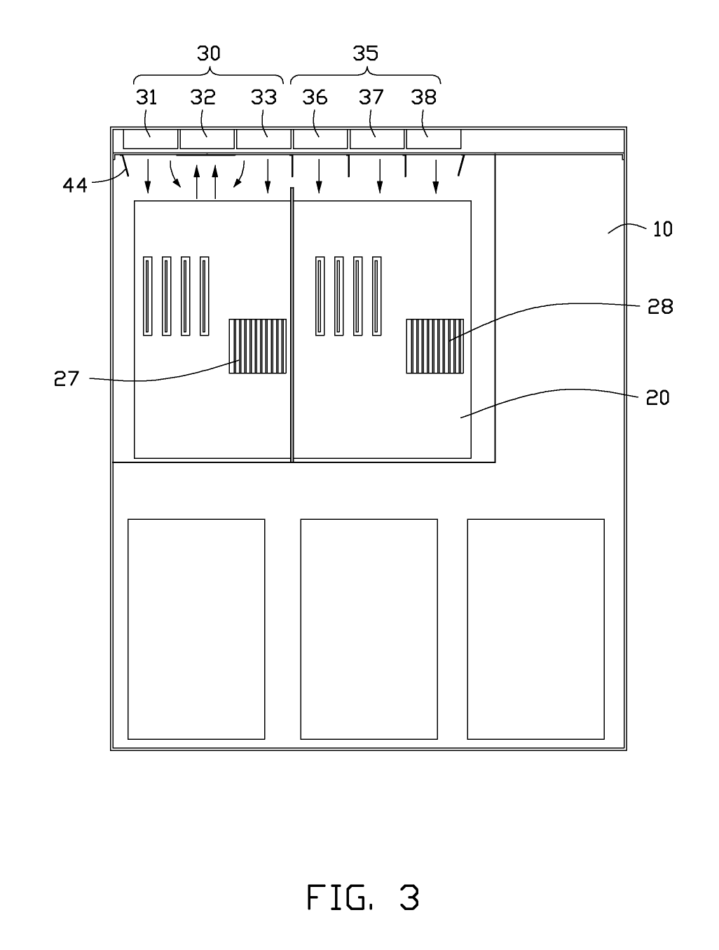

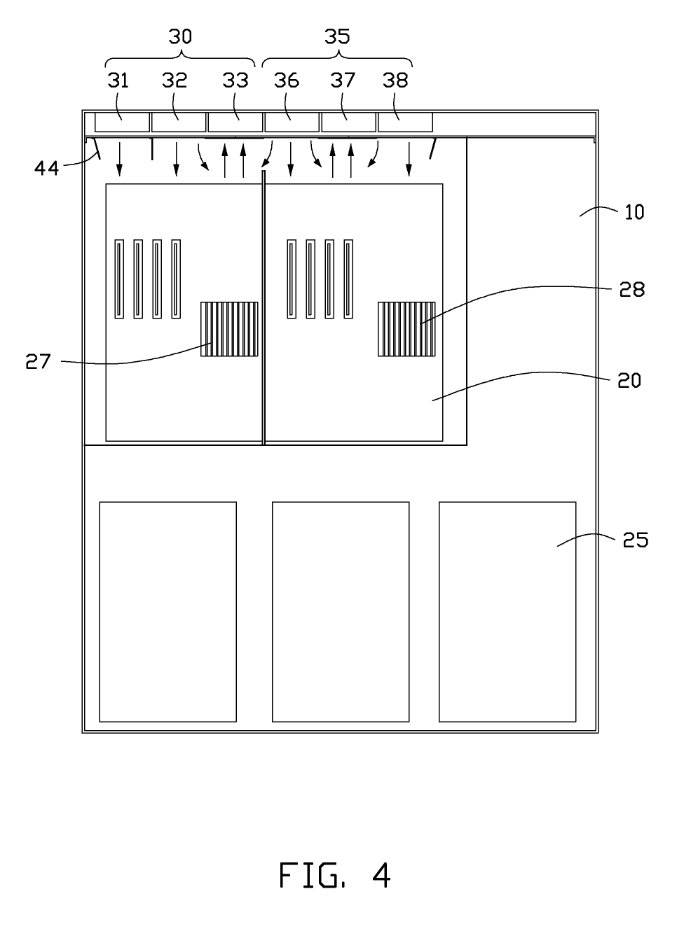

In use, referring to FIG. 3, when all of the fans 31 to 38 work at a normal state, the airflows from the fans 31 to 38 enter the air conducing cover 40 from the air entrances 43 for dissipating heat. Referring to FIG. 3, when the fan 32 of the first group of fans 30 stops working, return airflow will force the flaps 44 to rotate/swing for closing the corresponding air entrance 43 to prevent the return airflow from exiting through the entrance 43. Referring to FIG. 4, when the fan 33 of the first group of fans 30 and the fan 37 of the second group of fans 35 stop working, return air flow will rotate the flaps 44 to close the two corresponding air entrances 43. The flaps 44 effectively prevent airflow from returning to electronic devices. Thus, the airflow of the fans is not easily lost from the stopped fans, and thus secures a stable dissipating heat.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An air conducting cover comprising:
a plurality of air entrances, each entrance including two opposite flaps;
wherein air flow enters the air entrances, when a reverse air flow tries to reversely pass through the air entrances, the reverse air flow closes the flaps.

2. The air conducting cover as claimed in claim 1, wherein the air conducting cover includes a middle partition and an end plate, the middle partition divides the air conducting cover into a first space and a second space.

3. The air conducting cover as claimed in claim 2, wherein the end plate defines the air entrances, the flaps are flexibly connected to the end plate.

4. The air conducting cover as claimed in claim 3, wherein each flap is made of metal or plastics, and can swing toward the left or right sides relative to the end plate.

5. The air conducting cover as claimed in claim 2, wherein a width of each flap is substantially half of the width of the air entrance.

6. The air conducting cover as claimed in claim 2, wherein the flaps are positioned at a brim and angled toward the corresponding air entrance relative to the end plate, the other flaps are substantially perpendicular to the end plate.

7. An electronic device, comprising:
a chassis,
a group of fans;
an air conducting cover defining a plurality of air entrances, the fans respectively facing the corresponding air entrance, each entrance including two opposite flaps;
wherein when a reverse air flow tries to reversely pass through the air entrances, the reverse air flow closes the flaps.

8. The electronic device as claimed in claim 7, wherein a first electronic component and a second electronic component are positioned in the chassis, the air conducting cover includes a middle partition, the middle partition divides the air conducting cover to a first space and a second space, the fans includes a first group of fans for dissipating heat in the first space, and a second group of fans for dissipating heat in the second space.

9. The electronic device as claimed in claim 8, wherein the air conducting cover includes an end plate defining the air entrances, the flaps are flexibly connected to the end plate.

10. The electronic device as claimed in claim 9, wherein each flap is made of metal or plastics, and can swing toward the left or right sides relative to the end plate.

11. The electronic device as claimed in claim 10, wherein the flaps are positioned at a brim are angled toward the corresponding air entrance relative to the end plate, the other flaps are substantially perpendicular to the end plate.
